(19) United States
(12) Patent Application Publication
(10) Pub. No.: US 2004/0081322 A1
(43) Pub. Date: Apr. 29, 2004

(54) Method and arrangement for processing noise signal from a noise source

(76) Inventors: Michael Schliep, (US); Szaboles Törgyekes, Bogenstrasse (DE); Rolf White, Gundelsheim (DE); Walter Zipp, Stuttgart (DE)

Correspondence Address: CROWELL & MORING LLP, INTELLECTUAL PROPERTY GROUP, P.O. BOX 14300, WASHINGTON, DC, 20044-4300, US

(21) Appl. No.: 10/451,415

(22) PCT Filed: Dec. 12, 2001
(86) PCT No.: PCT/EP01/14623

(30) Foreign Application Priority Data
Dec. 22, 2000 (DE) 100-64-756.1

(51) Int. Cl. H03G 3/20; H04R 29/00

(52) U.S. Cl. 381/57; 381/56; 381/71.2; 381/94.1

(57) ABSTRACT

For locating, identifying and classifying noise sources inside and outside spaces, the invention provides a method for processing noise signals of a noise source, in which a plurality of noise signals (SQ1 to SQ4) are detected in a location-related manner and examined by means of a sound analysis on the basis of signal features in such a way that parameters underlying the noise source (G1 to G4) are determined.

The invention relates to a method for processing noise signals of a noise source, e.g. a traveling vehicle, a workshop, in a space, e.g. in the surrounding area. Furthermore, the invention relates to an arrangement for processing noise signals of a noise source.

In order to comply with legal noise limit values, e.g. in the context of operating a machine in a workshop, in the context of aircraft taking off and landing, in noise-critical zones, e.g. in residential areas or in the context of vehicles driving past, noise reduction measures on the object are known, which are intended to lower the machine, aircraft or traffic noise affecting the surroundings and, accordingly, to improve the working environment, living environment and traveling comfort. By way of example, low-noise exhaust gas and intake systems, largely resonance-free propulsion units or sound-absorbing bodywork are known for sound reduction purposes for objects, e.g. road or rail vehicles, aircraft or machines. What is disadvantageous in this case is that the noise reduction measures on the object and, resulting therefrom, the reduction of the noise level are limited. At the present time, measures or ambient conditions that influence the noise level, such as e.g. low-noise highway or meteorological ambient conditions, are taken into account only preliminarily with regard to complying with the noise limit values.

Furthermore, it is customary to provide stationary, passive measuring devices for the detection and monitoring of emission values such as e.g. of benzene and particulate limit values. In this case, the sound emission value occurring at this location of the measuring device is also measured, if appropriate. In this case, such a passive, location-related sound emission measurement is not suitable for identifying and classifying noise sources generating the noise level. Moreover, noise reduction measures over and above the measures on the object are not made possible.

Therefore, it is an object of the invention to specify a method for processing noise signals of a noise source in which a noise emission caused by the noise source is detected and determined in a particularly simple and reliable manner. Furthermore, the intention is to specify an arrangement which is particularly suitable for carrying out the method.

The first-mentioned object is achieved according to the invention by means of a method for processing noise signals of a noise source, in which a plurality of noise signals are detected in a location-related manner and examined by means of a sound analysis on the basis of signal features and parameters underlying the noise source are determined. Such joint detection of a plurality of noise signals and the spatial and/or temporal analysis thereof enable location, identification, classification and assessment of the noise source generating the noise signals. The noise signals are preferably detected simultaneously. In this case, the method can be used both in closed spaces and in the open. Consequently, it becomes possible to identify critical noises in the open, e.g. a loud bang, or temporally fluctuating noises in a space, which indicate e.g. a functional or operational fault or capacity utilization of a rotary machine in a machine room. Using suitable measurement sensors and fast signal processing for monitoring running machine installations, such as motors or turbines, indications of possible operating disturbances can be obtained on the basis of the sound analysis. A documentation of temporal and/or spatial behaviors of the noise source is made possible through the sound analysis of the signal features of the noise signals detected and, resulting therefrom, on the basis of the determination of parameters of the noise source causing the sound or noise signals. As an alternative or in addition, on the basis of the noise signals determined and the parameters determined for the underlying noise source, it is possible to implement noise reduction or noise lowering measures, e.g. it is possible to implement noise-reducing closed-loop and/or open-loop control measures directly at the noise source.

In this case, the invention is based on the consideration that, in order to comply with noise limit values in the open, e.g. in residential areas or in the vicinity of hospitals, or in closed spaces, e.g. in workshops or machine rooms, the sound emission occurring in this environment should be detected and monitored. In this case, not only should the sound emission value be detected as a local variable, rather the sound or noise source accounting for these sound emission values should be determined, located, classified and assessed. To that end, in an advantageous manner, the amplitude, frequency and/or phase of the or each noise signal detected are determined and analyzed as signal features of said noise signal. By way of example, on the basis of a level or amplitude comparison of the different location-related noise signals, it is possible to effect a location-related evaluation of the noise source causing said noise signals. In the case of from, for example, three noise signals with temporally significant features which are detected spatially at different locations, the noise source is located by propagation time measurement and triangulation. Furthermore, conclusions about the sound power of the noise source are possible on the basis of the amplitude or the sound intensity level of the respective noise signals.

The sound analysis is expediently performed on the basis of a time, frequency and/or level analysis. For this purpose, by way of example, for a sound spectrum characterizing the respective noise signal, the dependence of the sound pressure level on frequency is determined by means of a frequency analysis, e.g. a Fast Fourier Transformation (called FFT for short). Sampling rate, block length or interval of the underlying sound or noise signal can preferably be determined on the basis of the Fast Fourier Transformation.

In an advantageous manner, the type, position and/or state of the noise source is determined as parameters of said noise source. For this purpose, by way of example, the type of the noise source, e.g. a siren of a service vehicle, or the position of the noise source is determined on the basis of the features of the noise signal determined by means of the sound analysis, e.g. the interval, or on the basis of the combination of a plurality of noise signals. As state of the noise source, a movement of the noise source or an operating state of the noise source is determined on the basis of the sound analysis of the noise signals.

The sound analysis is expediently performed in the event of a noise limit value being exceeded. This enables a differentiated sound analysis. What is performed, by way of example, is a sound analysis of the measured noise signals and, resulting therefrom, location, identification, classification and assessment of the underlying noise source given the presence of critical noises, e.g. in the event of a detonation bang in the open, or in the event of a bang caused by a traffic accident, or in the event of a temporally fluctuating noise which indicates irregular running of a rotary machine. Preferably, a PRE trigger for maintaining a temporary ring memory is used for the sound analysis performed on account of a noise limit value being exceeded.

Expediently, at least one of the signal features of the noise signal is stored in the form of a noise pattern. By way of example, the frequency spectrum or the level spectrum of recurring noise signals is stored in the form of patterns for later identification of identical future noise signals. For particularly rapid identification and/or classification of the noise signals and thus of the noise source, at least one of the signal features of the noise signal is compared with stored noise patterns. This enables a particularly simple and rapid determination and assignment of parameters of the underlying noise source.

As an alternative or in addition, preferably external data, in particular meteorological data, optical data, time data, time-of-day data, are taken into account in the sound analysis of the noise signals detected. As a result of this, possible interference signals, such as e.g. of rain noises, can be eliminated from the noise signals detected in the open. Furthermore, it is possible to use the stored signal features, noise signals or noise patterns in connection with the detected time data, in particular time-of-day data, for evaluations, e.g. statistics. The quality of the identification of the underlying noise source is thus improved. Moreover, long-term considerations of local sound emissions in the open or in a space are made possible.

Furthermore, optical data, e.g. an image of an object with its surroundings or an image of a space, are preferably detected. On the basis of the optical data, possible absorption or reflection locations can be identified and taken into account in the sound analysis. Furthermore, by means of the noise source data obtained from the image and the parameters that can be derived therefrom, such as type, form, dimensioning and/or state, e.g. movement, can be used for the plausibility check of the acoustically detected noise signals and the signal features and parameters of the noise source determined therefrom. Particularly reliable identification and classification of the noise source or of the object or of the result is thus made possible.

A self-learning system is advantageously used for the determination and classification of the signal features of the noise signal and/or the parameters of the noise source. Various forms of artificial intelligence, e.g. neural networks, fuzzy logic and/or expert systems, are used as self-learning systems. Fuzzy values, such as e.g. “loud” or “less loud” rain noises, can be taken into account as a result of this. Furthermore, such systems can also be used for classification, e.g. for taking account of age-dictated changes in the parameters of the identified noise source. As an alternative or in addition, the stored noise patterns are adapted by means of neural networks on the basis of the currently or instantaneously detected noise signals of the identified noise source.

In an advantageous manner, the signal features and/or the parameters are fed to an open-loop and/or a closed-loop control system, an information system and/or an alarm system. The use of the detected noise signals and/or of the determined parameters of the noise source, e.g. as manipulated variable or setpoint value in an open-loop and/or closed-loop control system, e.g. load control of a vehicle driving past which causes a driving noise exceeding the noise limit values, enables the noise level to be limited or reduced.

The second-mentioned object is achieved according to the invention by means of an arrangement having a plurality of noise sensors for the location-related detection of noise signals and a central data processing unit for the sound analysis of the noise signals on the basis of at least one signal feature and for the determination of at least one parameter characterizing the noise source. Such a use of a plurality of noise sensors arranged for location-related detection at different locations in the open or in a closed space enables, by means of the logical combination thereof and the sound analysis of, the detected noise signals, location, identification, classification and assessment of noise sources, e.g. vehicle driving past or running turbine of a power station, or events, e.g. a braking noise, a bang. By way of example, a central personal computer or another programmable control unit serves as data processing unit.

Directional microphones are expediently provided as noise sensors. Different directional microphones are provided depending on the type and embodiment of the arrangement. By way of example, for a direction-related assignment of the noise source, a plurality of microphones with a directional characteristic, e.g. toward all four points of the compass, are arranged largely at one location in the space or in the open and there is arranged a microphone with an omnidirectional characteristic. Depending on the type and embodiment, acoustic sound sensors or noise sensors can be arranged in a distributed manner at different locations in the space or in the open. For the spatial and/or temporal assignment of the noise source, the noise sensors are connected to the central data processing unit by means of data transmission units. As an alternative or in addition, provision is made of airborne-sound transducers, structure-borne sound transducers for detecting object- or position-related acoustic signals.

The data processing unit preferably comprises a means for determining amplitude, frequency and/or phase of the or each noise signal. In this case, the means serves, in particular, for determining the amplitude, phase or frequency spectrum of the noise signals. As a result of this, identification, classification and assessment of the noise source, generating the noise signals, over and above the customary noise detection are possible for example by means of the determined pulse sequence of the sound or noise signals. By way of example, sudden energy releases, as occur e.g. as a result of mechanical deformations in the event of an accident, can be identified and classified by means of the characterizing sound pulses.

A means for determining type, position and/or state of the noise source is expediently provided. For this purpose, the means has a sound analysis module, for an amplitude, frequency and/or phase analysis. By way of example, the sound analysis module serves for the analysis of the noise amplitude and the noise sequence, in particular the sound pulse sequence. By way of example, the direction of acoustic incidence of the noise signals characterizing an individual noise source and also the position of the noise source can be determined depending on the logical combination of the noise signals which are detected at different locations, and on the basis of the amplitude analysis.

In a further advantageous refinement, the data processing unit comprises a means for monitoring a noise limit value. An event-controlled sound analysis is made possible through such monitoring, e.g. of a maximum permissible noise limit value by at least one of the detected noise signals for an area to be monitored or a space to be monitored. As an alternative, depending on the type and embodiment of the data processing unit, a permanent sound analysis can be performed for the relevant area or the relevant space.

Preferably, a data memory for storing at least one of the signal features of the noise signal in the form of a noise pattern is provided. By way of example, the noise sources localized and/or identified as steady-state, cyclic or nonsteady-state are characterized by their associated frequency, amplitude and/or phase spectra of the noise signals, e.g. their sound pulse sequences, which are stored in the form of patterns. For this purpose, the data processing unit expediently comprises a database with a noise pattern library. In this case, the database is continuously updated and supplemented by instantaneously detected and characteristic noise signals and the associated spectra thereof.

In a preferred embodiment, provision is made of a means for comparing at least one of the signal features of the noise signal with stored noise patterns for the determination and assignment of parameters of the underlying noise source. Such a comparison module enables a particularly simple and rapid identification of relevant noise sequences characterizing noise sources and hence a rapid identification of the noise source. In a preferred embodiment, a means for analyzing the parameters is provided, which examines the parameters on the basis of the sound analysis in a plurality of iteration steps for identifying significant aspects or patterns within a noise, such as e.g. significant frequency patterns.

In addition, an optical system for detecting optical data is preferably provided. The recording of an image of the surroundings of the noise sensors arranged in a distributed manner in a space or in the open on the basis of the optical system enables a supplementary determination of the noise source or a plausibility check with respect to the noise source identified on the basis of the sound analysis. Furthermore, absorption or reflection areas can be identified and taken into account in the sound analysis of the noise signals. Moreover, in a space to be monitored, e.g. a workshop, a room or building safeguard, i.e. an intrusion safeguard, is made possible both optically and acoustically.

For taking account of data which influence the noise signals, a recording unit for detecting meteorological data is preferably provided. This makes it possible to eliminate e.g. heavy rain noises or hail noises from the noise signals in the sound analysis. Furthermore, provision is preferably made of a means for determining and classifying the signal features of the noise signal and/or the parameters of the noise source on the basis of a self-learning system. In this case, various forms of artificial intelligence, e.g. neural networks and/or fuzzy logic, can be used. In this case, the identification, localization and classification of the noise signals and/or of the underlying noise source into steady-state, cyclic or nonsteady-state is effected on the basis of fuzzy values and the logical combinations thereof.

An external open-loop and/or closed-loop control system is advantageously provided. By way of example, external safety systems can be driven by means of the detection and assessment of the noise signals performed on the basis of the sound analysis. As an alternative, the noise signals can be used for noise-lowering open-loop and/or closed-loop control systems.

The particular advantages achieved with the invention are that, for permanent monitoring of sound and noise emissions and also for reliable identification of noise-causing noise sources, objects or events, a plurality of noise signals are detected in a location-related manner and analyzed by means of a sound analysis on the basis of signal features in such a way that at least one parameter underlying the noise source is determined. Such a determination of a parameter of the noise-emitting noise source, e.g. a hum of a rotary machine in a motor works or a bang as a result of a traffic accident, affords a use of the arrangement both in closed spaces, e.g. in workshops or production buildings, or in the surroundings, e.g. along a freeway. In this case, the detected data can be used to make statements about the steady-state, cyclic or nonsteady-state behavior of noise sources in a particularly simple manner.

Exemplary embodiments of the invention are explained in more detail with reference to a drawing, in which:

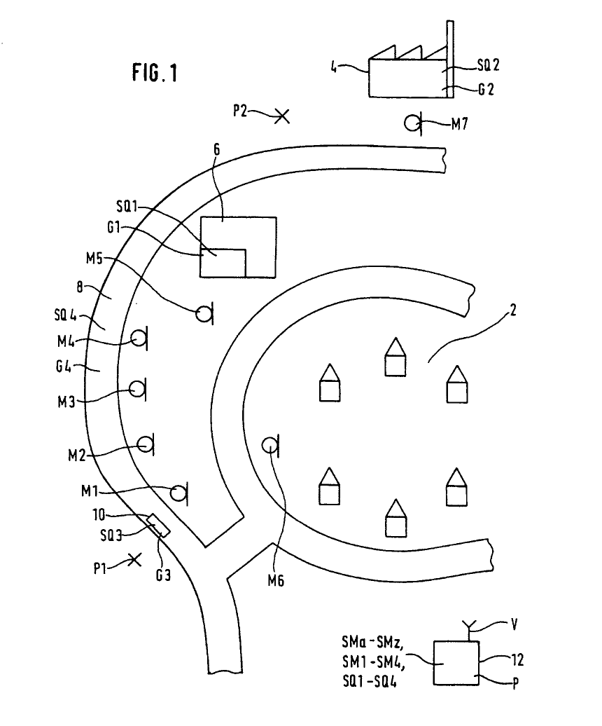

FIG. 1 schematically shows an arrangement for processing noise signals with a plurality of noise sensors and a central data processing unit,

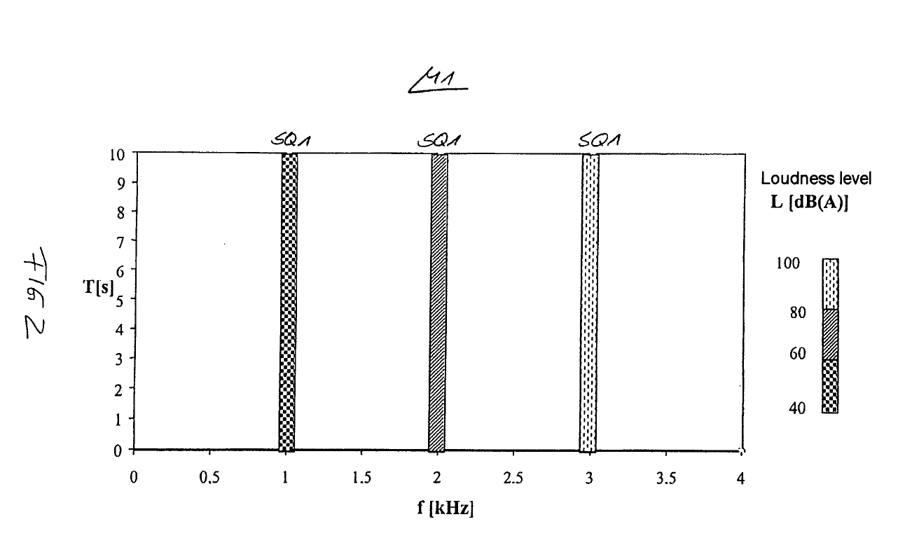

FIG. 2 shows a diagram for a first noise pattern,

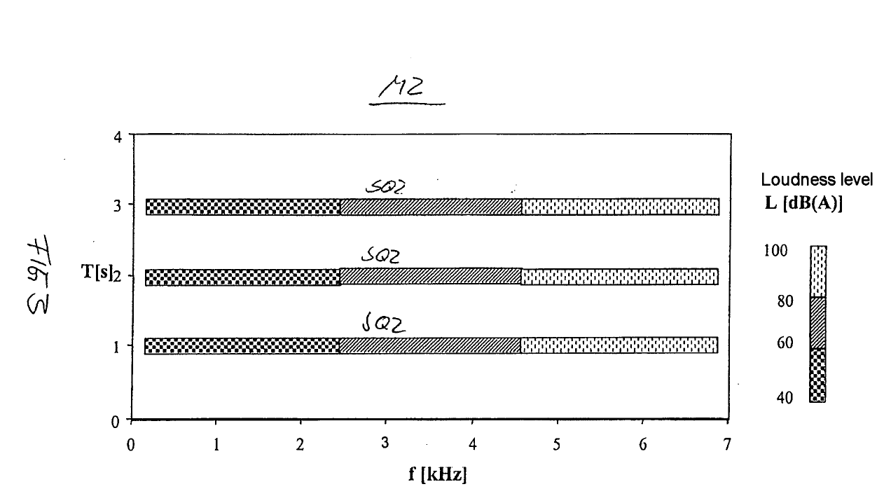

FIG. 3 shows a diagram for a second noise pattern,

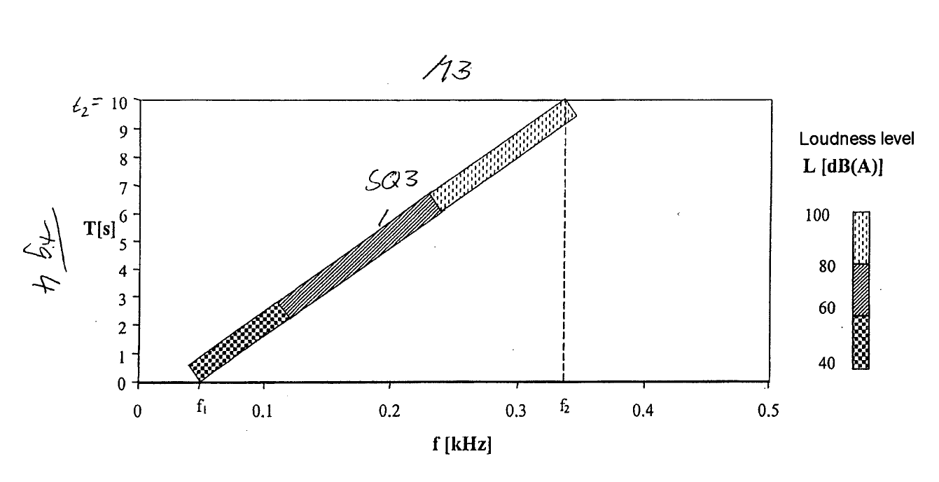

FIG. 4 shows a diagram for a third noise pattern,

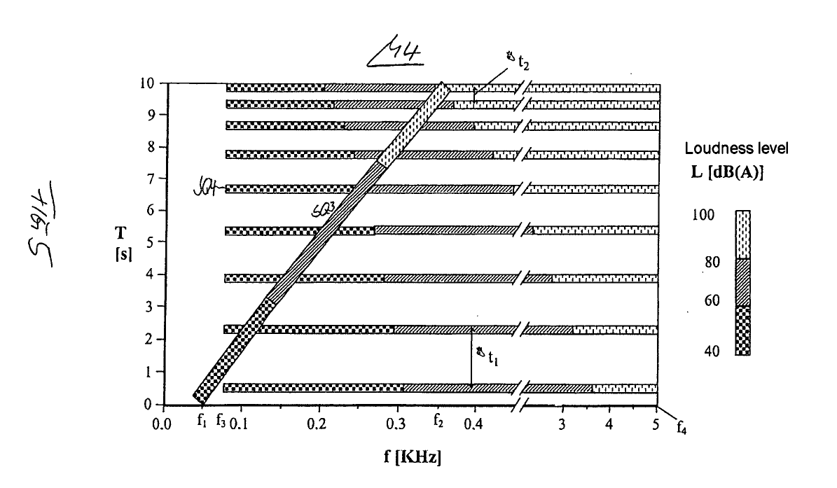

FIG. 5 shows a diagram for a fourth noise pattern,

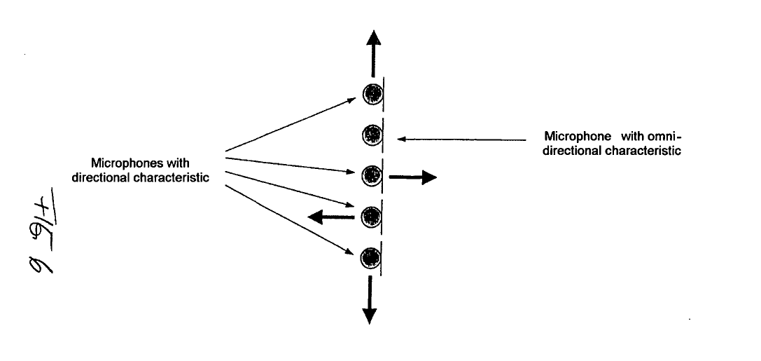

FIG. 6 schematically shows an alternative for the arrangement in accordance with FIG. 1,

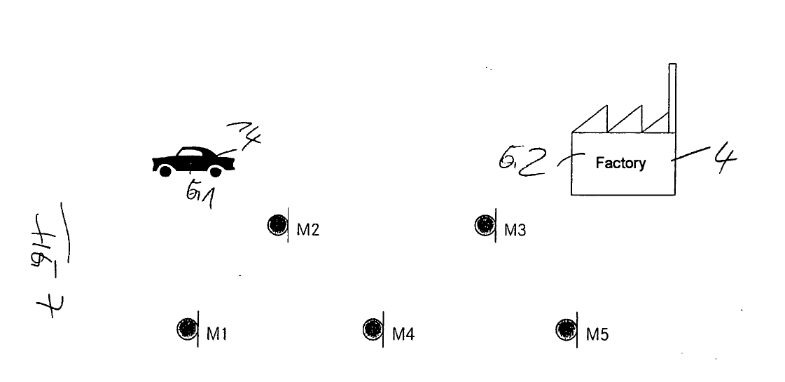

FIG. 7 schematically shows a further alternative for the arrangement in accordance with FIG. 1, and

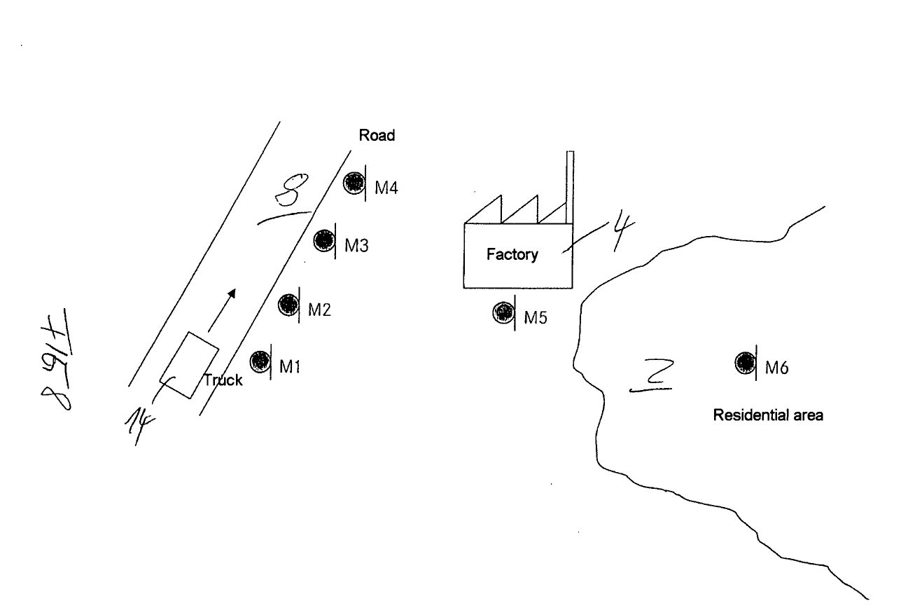

FIG. 8 schematically shows a further alternative for the arrangement in accordance with FIG. 1.

Mutually corresponding parts are provided with the same reference symbols in all the figures.

In FIG. 1 there is an arrangement 1 for processing noise signals SQ1 to SQ3 of a noise source G1, G2 and G3, respectively. For the location-related detection of the noise signals SQ1 to SQ3, a plurality of noise sensors M1 to M7 are arranged at different locations in the open. By way of example, the noise sensor M6 is provided for the location-related detection of noises imitated in a residential area 2. The noise sensor M7 or M5 is respectively provided for detecting noise signals SQ2 or SQ1, which are caused by the noise source G2, e.g. an industrial installation 4, or by the noise source G1, e.g. a fan of an air-conditioning system in a shopping center 6. For a motorcycle 10 traveling on a highway 8, a plurality of noise sensors M1 to M4 are arranged along the highway 8 for the direct detection of the noise signals SQ3 of the noise source G3, e.g. the engine.

The noise sensors M1 to M7 are connected via a data transmission unit (not specifically illustrated) to a central data processing unit 12 for the sound analysis of the noise signals SQ1 to SQ3 detected by means of the noise sensors M1 to M7 and also for the determination of parameters P of a noise source G1 to G3, which is unknown and has not been identified at the instant of the measurement detection. By way of example, wire-free or wire-based systems, e.g. radio systems or data bus systems, are provided as data transmission unit. By way of example, a personal computer of an environmental measurement station monitoring emission values serves as data processing unit 12. By way of example, directional microphones, acoustic measurement transducers, airborne-sound or structure-borne sound sensors are used as noise sensors M1 to M7.

By means of the noise sensor M6 arranged in the residential area 2, the following noise signals SQ1 to SQ4 of the four noise sources G1 to G4 are detected:

1. The noise signal SQ1 issuing from the noise source G1, a fan of an air-conditioning system of the shopping center 6, in the immediate vicinity of the residential area,

2. The noise signal SQ2 issuing from the noise source G2, a press of the industrial installation 4, a few hundred meters away from the residential area,

3. The noise signal SQ3 issuing from the noise source G3, the motorcycle 10, and

4. A noise signal SQ4 of the noise source G4 issuing from the highway 8 of a bypass around the residential area 2 which describes a 180° arc of a circle around the noise sensor M6. The maximum permissible speed on the bypass is 100 km/h, for example.

At the noise sensor M6 or monitoring microphone, noise signals SQ1 to SQ4 receiving at the instant t=0 are examined by means of a sound analysis, in particular an amplitude, frequency or phase analysis, for determining parameters P of the noise source G1, G2, G3 or G4 generating the noise signals SQ1, SQ2, SQ3 or SQ4, respectively in particular for identifying noise patterns SM1 to SM4 describing the noise sources G1 to G4. In this case, a noise pattern SM1 to SM4 identifies characteristic noise levels (or noise level ratios) over frequency and time of the associated noise sources G1 to G4.

Depending on the type and construction of the data processing unit 12, the sound analysis of the detected noise signals SQ1 to SQ4 can be formed when a permissible or maximum noise limit value, in particular a limit value for the noise level, is exceeded and thus in a manner dependent on predeterminable and/or instantaneous acoustic or optical conditions. By way of example, in the case of an image which is detected by an optical system 14 and represents a critical situation, e.g. a traffic accident or a disturbance in the press, e.g. a fire, through a corresponding signal the sound analysis can be performed by means of the data processing system 12. Through such an event-controlled sound analysis, the arrangement 1 can be implemented both for acoustic and/or optical location/localization, identification, classification and/or assessment of noise signals SQ1 to SQ4 and/or noise sources G1 to G4. By way of example, a fire can be identified in the case of a [lacuna] on the basis of the optical data detected by means of the optical system 14. In combination with the acoustic evaluation of noise signals SQ detected at the same instant by means of at least one of the noise sensors M1 to M7, a possibly preceding explosion or detonation can be identified.

A noise pattern SM1 describing the noise source G1 (=the fan of the air-conditioning system) is illustrated by way of example in FIG. 2. The fan runs for example at a constant rotational speed and, in the process, generates steady-state single tones which are emitted as airborne sound and thus noise signals SQ1. These noise signals SQ1 are determined by its rotational speed and the number of its rotor blades. The fan's noise pattern SM1 resulting from the single tones received as noise signals SQ1 is illustrated in FIG. 2 in the form of a Campbell diagram. In this case, the Campbell diagram shows functions of two variables—here level over frequency and time. The Campbell diagram for the fan of the air-conditioning system of the shopping center is characterized by those characteristic single tones which appear as fixed frequencies with a constant level over time in the diagram. They are discernable as straight lines parallel to the time axis and intersect the frequency axis at the instant t=0 s at the respective frequency.

A noise pattern SM2 describing the noise source G2 is illustrated by way of example in FIG. 3. The noise source G2, the industrial installation 4, e.g. a press for sheet-metal processing, presses a shaped part every second. The noise signal SQ2 generated in the process has a typical pulse character. The bandwidth of the associated frequency range runs from 30 Hz to 6 800 Hz, for example. The noise pattern SM2 is illustrated by way of example in the form of a Campbell diagram. The Campbell diagram for the press is characterized by the characteristic single pulses or noise signals SQ2 running parallel to the frequency axis from 30 Hz to 6 800 Hz at intervals of one second. The line representing the respective single pulse or the noise signal SQ2 describes the frequency-related loudness level of the single pulse in accordance with the texture scaling.

A noise pattern SM3 describing the noise source G3 is illustrated by way of example in FIG. 4. The noise source G3, e.g. a motorcycle 10, turns at walking speed from the residential area 2 into the bypass at the point P1 (see FIG. 1). The motorcycle 10 accelerates with a uniform change in the engine speed from 1 000 min⁻¹ at the instant t₁=0 s to 11 000 min⁻¹ by instant t₂=10 s. The engine noise dominated by the ignition frequency f and thus the receiving noise signal SQ3 results, e.g. for a 4-cylinder/4-stroke engine as sweep (=changing tone) with the second engine order (double the engine speed) as frequency. This sweep thus runs from f₁=33.3 Hz (2nd engine order at 1 000 min⁻¹) at the instant t₁=0 s to f₂=366.6 Hz (2nd engine order at 11 000 min⁻¹) at the instant t₂=10 s. The loudness level of said sweep shall rise continuously in the process. On account of the circular arrangement of the bypass around the noise sensor M6 or the monitoring microphone in the residential area 2 (see FIG. 1), the distance between the moving noise source G3 (that is to say the motorcycle 10) and the noise sensor (M6) is approximately constant. Consequently, a frequency shift according to the acoustic Doppler effect does not occur. Consequently, the noise pattern SM3 for the noise source G3, as illustrated in the form of a Campbell diagram in FIG. 4, has a linear profile. The Campbell diagram for the motorcycle 10 and hence for the noise source G3 is described by the characteristic profile of the sweep on account of the change in ignition frequency during the acceleration process. This characteristic profile can be discerned as a diagonal line connecting the points P1 (t₁=0 s; f₁=33.3 Hz) and P2 (t₁=10 S; f₂=366.6 Hz). The increase in loudness level during this change in speed is described by the texture scaling.

A further noise pattern SM4 for noise signals SQ6 receiving by means of the noise sensor M6, which describes a combination of humming and knocking noises, is illustrated by way of example in FIG. 5. In this respect, the motorcycle 10 (=noise source G3) turns at walking speed from the residential area 2 into the bypass (point P1 in FIG. 1). The motorcycle 10 accelerates with a uniform change in the engine speed from 1 000 min⁻¹ at the instant t₁=0 s to 11 000 min⁻¹ at the instant t₂=10 s. A stone has become caught in the tire tread of the motorcycle 10 and strikes the asphalt once during every wheel revolution and generates a pulse having a bandwidth of 90 Hz to 5 kHz in the process. This knocking noise is detected together with the changing ignition frequency of the high-revving engine by the noise sensor M6 in the residential area 2.

The resulting noise pattern SM4 is illustrated in the form of a Campbell diagram in FIG. 5. In this case, the noise pattern SM4 comprises superposed noise signals SQ3 and SQ4 characterizing the noise source G3, i.e. the engine noise and the traveling noise. The line running obliquely between the frequencies f1 and f2 describes the varying ignition frequency of the high-revving engine and hence the noise signal SQ3. The lines running parallel to the frequency axis describe the knocking noises of the stone on the asphalt and hence the noise signal SQ4. The time interval At between two knocks corresponds to one wheel revolution. Between the starting speed (n₁=1 000 min⁻¹) and the end speed (n₂=11 000 min⁻¹) of the engine, said time interval decreases continuously from Δt₁ to Δt₂.

During the operation of the data processing unit 12, the detected noise signals SQ1 to SQ4 are examined by means of a sound analysis on the basis of signal features in such a way that the latter are assigned to the underlying noise source G1 to G4 and parameters P underlying the noise source G1 to G4, such as e.g. fan in operation or motorcycle 10 is traveling or stationary, are determined. Depending on the type and construction of the data processing unit 12, the sound analysis is performed in a manner dependent on a noise level which has exceeded a noise limit value and is detected at the noise sensor M6. In this case, the data processing unit 12 comprises a corresponding means, e.g. a corresponding functional module realized by software, for limit value monitoring.

In this case, the sound analysis can be performed on the basis of different analyses, e.g. time, frequency and/or level analyses. For this purpose, the sound analysis comprises algorithms which examine the relevant noise signal SQ1 to SQ4 for characteristic signal features, such as e.g. fixed frequencies (fan), short broadband pulses (press) and sweeps (accelerating motorcycle). Such an algorithm is e.g. the method described below for identifying characteristic signal features of the noise signals SQ1 to SQ4 of an underlying noise pattern SM1 to SM4. The characteristic signal features of the noise pattern SM1 to SM4 are used as identification criteria for the respective noise pattern SM1 to SM4, on the basis of which a comparison is made with noise patterns SMₐ to SM_{z} stored in a database of the data processing unit 12 and with noise patterns SM1 to SM4 detected on the basis of the noise sensors M1 to M7. This comparison enables noise signals SQ1 to SQ4 detected in the microphone M6 to be assigned to the causal noise source G1 to G4.

By way of example, the detected noise signals SQ1 to SQ4 of the measurement locations or noise sensors M1 to M7 are stored as time data in a ring memory. In the event of a threshold value or noise limit value being exceeded, e.g. at the microphone M6 in the residential area 2, the content of the ring memory is stored with a predeterminable lead time before the occurrence of the noise limit value being exceeded. Characteristic noise or signal features are analyzed on the basis of the sound analysis in accordance with the graphical aspects in the Campbell diagram. A pixel in the Campbell diagram (depending on the resolution of the Fast Fourier Transformation (FFT)) corresponds to a loudness level value of an analyzed frequency and time bandwidth within the detection ranges. Graphical relationships (cf. noise patterns SM1 to SM4 in FIGS. 2 to 5) correspond to acoustic signal features which are assigned to concrete causes or noise sources G1 to G4 on the basis of the database comparison and the comparison with other noise signals SQ1 to SQ4 of other noise sensors M1 to M7 (e.g. near-field microphones, directional microphones).

A preferred assessment of detected noise signals SQ1 to SQ4 is e.g. the Fast Fourier Transformation (called FFT for short) of the microphone signals and the calculation of the so-called A-weighted sound pressure level. The A-weighted sound pressure level is defined as follows:

$$\begin{matrix}{L}_{P} = 10 {{log}_{10} ( \frac{P}{{P}_{0}} )}^{2} where P = measured alternating sound pressure \\ {P}_{0} = 2 {c}^{- 5} {P}_{a}\end{matrix}$$

Crucial assessment criteria of the FFT are, for example, sampling rate (chosen to be fixed e.g. at 25 kHz) or block length.

If frequencies lying close together are to be resolved for the identification of a noise pattern SM1 to SM4, it is necessary to choose a different block length than in the case of temporally closely successive pulses (in accordance with the principle of the noise patterns SM1 to SM4).

A sound or pattern analysis may comprise a plurality of mutually independent processes which employ different FFT block lengths, for example, as assessment criteria. This exemplary choice of the value of an assessment criterion may depend on the current process itself or on external specifications. In this respect, the data processing unit 12 preferably has a means for analyzing the parameters P on the basis of the sound analysis, the parameter analysis being carried out in a plurality of iteration steps in order to identify significant aspects or noise patterns SM1 to SM4 within a detected noise signal SQ1 to SQ4, such as e.g. frequency and loudness level of a hum, bandwidth, loudness level and time interval of a repeatedly knocking noise. In this case, it is possible to vary the assessment criteria of the sound analysis on the basis of input quantities.

As input signal, an optical pattern recognition (over time) may also be effected analogously to the acoustic pattern recognition. For this purpose, provision is additionally made of an optical system (not illustrated) for detecting optical data of the surroundings or of a space. On the basis of the comparison of the analyses, relationships of causes and effects can be described, assessed and stored. Another application may consist e.g. in a concrete recognition specification of specific processes. This may be e.g. the targeted search for high-revving motorcycles or approaching utility vehicles, the occurrence of which is filtered out from the detected noise signals SQ1 to SQ4. A further application is afforded e.g. in the context of noise-critical maintenance work; if the latter cannot be carried out under normal weather and traffic conditions owing to night rest, the noise-critical activity may nevertheless be permitted in the case of loud background noise such as drumming rain or high volume of traffic (on account of a diversion due to an accident). Depending on the type and embodiment of the data processing unit 12, the taking account of the data may be determined and controlled by external systems, such as e.g. by optical, meteorological or navigation systems, during the sound analysis on the basis of input quantities, e.g. instances of limit values being exceeded, and/or quality features.

FIG. 6 shows an embodiment for the arrangement 1 for a spatial and temporal assessment of noise sources G1 to G4. The arrangement 1 comprises five noise sensors M1 to M5 arranged at a measurement point, e.g. closely one above the other on a lamppost on a highway or on a carrier in a workshop. In this case, four of the five noise sensors M1 to M4 have a horizontal directional characteristic toward all four points of the compass. In this case, one of the five noise sensors M5 has a vertical directional characteristic, in particular an omnidirectional characteristic. A noise signal SQ1 to SQ4 exceeding the noise limit value is detected by means of the noise sensor M5 with an omnidirectional characteristic. At least one signal feature of the noise signal SQ1 to SQ4, e.g. level, frequency, phase, is examined and identified on the basis of the sound or pattern analysis of the data processing unit 12. The noise pattern SM1 to SM4 determined in this case is compared with regard to identity with the noise signals SQ1 to SQ4 receiving by means of the four directional microphones or noise sensors M1 to M4, as a result of which the direction can be determined on the basis of that noise sensor M1 to M4 with the same noise pattern SM1 to SM4 and the strongest level.

FIG. 7 shows a further embodiment of the arrangement 1 with a plurality of noise sensors M1 to M5. The noise sensors M1 to M5 are arranged as microphones with a vertical omnidirectional characteristic in a manner distributed uniformly on an examination site of an industrial installation. As an alternative, they may also be arranged in a closed space, e.g. in a workshop of the industrial installation 4. Noise signals SQ1 to SQ4 from the same noise source G1 to G4, e.g. the noise signal SQ1 of a vehicle 14 driving past or the noise signal SQ2 of the industrial installation 4, is received at different points in time by the noise sensors M1 to M5, arranged spatially at different locations, depending on the sound propagation distance covered and the resultant sound propagation time. The position of the noise or sound source G1 or G2, i.e. of the vehicle 14 or of the industrial installation 4, is determined on the basis of the given position of the noise sensors M1 to M5 and the determined sound propagation distance or sound propagation time for the respective noise sensor M1 to M5.

A further embodiment of the arrangement 1 is illustrated in FIG. 8. The arrangement 1 comprises six noise sensors M1 to M6. The noise sensors M1 to M6 are embodied as microphones with an omnidirectional characteristic. The noise sensors M1 to M6 are arranged at different measurement points in the examination area. The noise sensors M1 to M4 are arranged along the highway 8. The noise sensor M5 is arranged in the region near the industrial installation 4. The noise sensor M6 is arranged in the residential area 2. During the operation of the arrangement 1, a noise exceeding the noise limit value is detected by means of the noise sensor M6. The noise pattern SM1 underlying this noise signal SQ1 is compared with the noise patterns SM1 receiving by the other noise sensors M1 to M4 and noise pattern SM2 receiving by the noise sensor M5. In the event of correspondence between noise patterns SM1 (M1 to M4)=SM1 (M6) of different noise sensors M1 to M4 and M6, respectively, it becomes possible to identify and classify the noise source SQ1. An assessment of the detected noise signal SQ1 and thus also an assessment of the noise source G1 are also afforded on the basis of a level analysis. By way of example, on the basis of a combined frequency and level analysis taking account of external influences or data, such as e.g. with the elimination of interference or other noise signals such as rain noises, it becomes possible to make a statement about the state of the noise source G1, e.g. the vehicle 14 is accelerating or braking.

1. A method for processing noise signals (SQ1 to SQ4) of a noise source (G1 to G4),
characterized in that a plurality of noise signals (SQ1 to SQ4) are detected in a location-related manner and examined by means of a sound analysis on the basis of signal features and parameters underlying the noise source (G1 to G4) are determined.

2. The method as claimed in claim 1,
characterized in that the amplitude, frequency and/or phase of the noise signal (SQ1 to SQ4) is determined as signal features of said noise signal.

3. The method as claimed in claim 1 or 2,
characterized in that the sound analysis is performed on the basis of a time, frequency and/or level analysis.

4. The method as claimed in one of claims 1 to 3,
characterized in that the type, position and/or state of the noise source (G1 to G4) is determined as parameters of said noise source.

5. The method-as claimed in one of claims 1 to 4,
characterized in that the sound analysis is performed in the event of a noise limit value being exceeded.

6. The method as claimed in claim 5,
characterized in that the sound analysis performed on account of a noise limit value being exceeded is used [lacuna] a trigger for maintaining a temporary ring memory.

7. The method as claimed in one of claims 1 to 6,
characterized in that at least one of the signal features of the noise signal (SQ1 to SQ4) is stored in the form of a noise pattern (SM1 to SM4).

8. The method as claimed in one of claims 1 to 7,
characterized in that at least one of the signal features of the noise signal (SQ1 to SQ4) is compared with stored noise patterns (SMₐ to SM_{z}) for the determination and assignment of parameters of the underlying noise source (G1 to G4).

9. The method as claimed in one of claims 1 to 8,
characterized in that external data, in particular meteorological data, optical data, time data, operating parameters, are taken into account.

10. The method as claimed in one of claims 1 to 9,
characterized in that a self-learning system is used for the determination and classification of the signal features of the noise signal (SQ1 to SQ4) and/or the parameters of the noise source (G1 to G4).

11. The method as claimed in one of claims 1 to 10,
characterized in that the signal features and/or the parameters are fed to an open-loop and/or a closed-loop control system.

12. An arrangement (1) for processing noise signals (SQ1 to SQ4) of a noise source (G1 to G4),
characterized in that provision is made of a plurality of noise sensors (M1 to M7) for the location-related detection of noise signals (SQ1 to SQ4) and a central data processing unit (12) for the sound analysis of the noise signals (SQ1 to SQ4) on the basis of at least one signal feature and for the determination of at least one parameter characterizing the noise source (G1 to G4).

13. The arrangement as claimed in claim 12,
characterized in that directional microphones are provided as noise sensors (M1 to M7).

14. The arrangement as claimed in claim 12 or 13,
characterized in that a means for determining amplitude, frequency and/or phase of the noise signal (SQ1 to SQ4) is provided.

15. The arrangement as claimed in one of claims 12 to 14,
characterized in that a means for determining type, position and/or state of the noise source (G1 to G4) is provided.

16. The arrangement as claimed in one of claims 12 to 15,
characterized in that a means for monitoring a noise limit value is provided.

17. The arrangement as claimed in one of claims 12 to 16,
characterized in that a data memory for storing at least one of the signal features of the noise signal (SQ1 to SQ4) in the form of a noise pattern (SM1 to SM4) is provided.

18. The arrangement as claimed in one of claims 12 to 17,
characterized in that a database comprising a noise pattern library is provided.

19. The arrangement as claimed in one of claims 12 to 18,
characterized in that provision is made of a means for comparing at least one of the signal features of the noise signal (SQ1 to SQ4) with stored noise patterns (SMₐ to SM_{z}) for the determination and assignment of parameters of the underlying noise source (G1 to G4).

20. The arrangement as claimed in one of claims 12 to 19,
characterized in that an optical system for detecting optical data is provided.

21. The method as claimed in one of claims 12 to 20,
characterized in that a recording unit for detecting meteorological data is provided.

22. The arrangement as claimed in one of claims 12 to 21,
characterized in that provision is made of a means for determining and classifying the signal features of the noise signal (SQ1 to SQ4) and/or the parameters of the noise source (G1 to G4) on the basis of a self-learning system.

23. The arrangement as claimed in one of claims 12 to 22,
characterized in that an external open-loop and/or a closed-loop control system is provided.

24. The arrangement as claimed in one of claims 12 to 23,
characterized in that provision is made of a means for analyzing the parameters (P) on the basis of the sound analysis in a plurality of iteration steps for identifying significant aspects within a noise.
